(19) United States
(12) Patent Application Publication
(10) Pub. No.: US 2010/0190335 A1
(43) Pub. Date: Jul. 29, 2010

(54) Method of manufacturing semiconductor device

(75) Inventors: Yuichi Nakao, Kyoto (JP); Takahisa Yamaha, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/659,602

(22) Filed: Mar. 15, 2010

Related U.S. Application Data
(62) Division of application No. 11/945,766, filed on Nov. 27, 2007.

(30) Foreign Application Priority Data
Nov. 28, 2006 (JP) 2006-320649

(51) Int. Cl. H01L 21/768

(52) U.S. Cl. 438/653; 257/E21.584

(57) ABSTRACT

In a method of manufacturing a semiconductor device according to the present invention, a wiring trench is formed on the surface of an insulating film, and the inner surface of this wiring trench is thereafter coated with an alloy film made of an alloy material containing copper and a prescribed metallic element. After this coating with the alloy film, a copper film is laminated on the insulating film to fill up the wiring trench. Then, unnecessary portions of the copper film outside the wiring trench are removed, so that the surface of the copper film remaining in the wiring trench is generally flush with the surface of the insulating film. Thereafter heat treatment is performed. The prescribed metallic element is deposited on the wiring trench due to this heat treatment. Then, the prescribed metallic element deposited on the wiring trench is removed.

### CROSS-REFERENCE TO RELATED APPLICATION

This application is a divisional application of application Ser. No. 11/945,766, filed on Nov. 27, 2007.

### BACKGROUND OF THE INVENTION

1. Field of the Invention

The present invention relates to a semiconductor device and a method of manufacturing the same.

2. Description of Related Art

With the advance in integration of a semiconductor device, further refinement of a wiring is required. In order to suppress increase of wiring resistance resulting from such refinement of the wiring, the substitution of Cu (copper) having higher conductivity for Al (aluminum) generally employed as the wiring material is under consideration.

Since it is difficult to finely pattern Cu by dry etching or the like, a Cu wiring is formed by the so-called damascene process. In this damascene process, a fine wiring trench corresponding to a prescribed wiring pattern is first formed on an insulating film made of SiO₂ (silicon oxide). Then, a Cu film is formed on the insulating film by plating. The Cu film is formed in a thickness with which it fills up the wiring trench and covers the entire surface of the insulating film. Thereafter the Cu film is polished by CMP (chemical mechanical polishing). This polishing of the Cu film is continued until the portions of the Cu film outside the wiring trench are entirely removed and the surface of the insulating film outside the wiring trench is exposed. Thus, the Cu film remains only in the wiring trench, and a Cu wiring embedded in the wiring trench is obtained.

Cu has higher diffusibility into silicon oxide as compared with Al. When the Cu wiring (the Cu film) is directly formed on the insulating film made of silicon oxide, therefore, Cu may diffuse into the insulating film to cause a short circuit and the like between wiring.

Therefore, a barrier film must be formed between the insulating film and the CU wiring, in order to prevent Cu from diffusing into the insulating film. As a method of forming such a barrier film, for example, there is proposed a method of forming an alloy film made of an alloy of Cu and Mn (manganese) on the insulating film provided with the wiring trench in advance of the formation of the Cu film and performing heat treatment after the formation of the Cu film to diffuse Mn contained in the alloy film into the interface between the alloy film and the insulating film, thereby forming a barrier film made of MnₓSi_{y}O_{z} (x, y, z: numbers greater than zero) on this interface.

According to this method, however, unnecessary Mn not contributing to the formation of the barrier film remains in the Cu wiring, to disadvantageously increase the resistance of the Cu wiring.

As shown in FIG. 3, it is known that the specific resistance of Cu containing Mn is increased generally in proportion to the Mn content ratio. While the specific resistance of pure Cu is about 1.9 to 2.0 μΩ·cm, that of Cu containing 1% (at %) of Mn in atom number is about 5 to 6 μΩ·cm, for example. In a fine Cu wiring having a width of 60 to 70 nm, even slight increase of the specific resistance results in remarkable increase of the wiring resistance.

### SUMMARY OF THE INVENTION

An object of the present invention is to provide a method of manufacturing a semiconductor device and a semiconductor device which are capable of reducing the resistance of a copper film (copper wiring) embedded in a wiring trench.

One aspect of the present invention may provide a method of manufacturing a semiconductor device including: a wiring trench forming step of forming a wiring trench on a surface of an insulating film; an alloy film coating step of coating an inner surface of the wiring trench with an alloy film made of an alloy material containing copper and a prescribed metallic element; a copper film stacking step of stacking a copper film on the insulating film to fill up the wiring trench after the alloy film coating step; an unnecessary film portion removing step of removing unnecessary portions of the copper film outside the wiring trench; a metallic element depositing step of depositing the prescribed metallic element on the wiring trench by performing heat treatment after the unnecessary film portion removing step; and a deposited metal removing step of removing the prescribed metallic element deposited on the wiring trench after the metallic element depositing step.

That is, after the wiring trench is formed on the surface of the insulating film, the inner surface of this wiring trench is coated with the alloy film made of the alloy material containing copper and the prescribed metallic element. After this coating with the alloy film, the copper film is laminated on the insulating film to fill up the wiring trench. Then, the unnecessary portions of the copper film outside the wiring trench are removed, so that the surface of the copper film remaining in the wiring trench is generally flush with the surface of the insulating film. Thereafter the heat treatment is performed. The prescribed metallic element is deposited on the wiring trench due to this heat treatment. Then, the prescribed metallic element deposited on the wiring trench is removed.

According to the conventional method, the copper film (Cu film) is formed by plating after the formation of the alloy film. Thereafter the heat treatment is performed, so that the barrier film is formed on the interface between the alloy film and the insulating film. After the formation of the barrier film, the unnecessary portions of the copper film outside the wiring trench are removed, whereby the copper wiring embedded in the wiring trench is obtained. The mechanism through which the unnecessary metallic element such as Mn remains in the copper wiring formed along these steps is not exactly obvious. When the copper film is formed by plating, however, impurities may conceivably be mixed into the copper film to clog the grain boundaries of copper atoms forming the copper film, thereby hindering movement of the metallic element such as Mn along the grain boundaries.

On the other hand, according to the above-described inventive method, the unnecessary portions of the copper film outside the wiring trench are removed, so that the copper film is reduced in thickness and the grain boundaries of copper atoms not clogged with impurities are exposed on the surface of the copper film in the wiring trench. In the heat treatment after this removal of the unnecessary portions, therefore, the prescribed metallic element contained in the alloy film easily moves along the grain boundaries, and the prescribed metallic element is excellently deposited on the wiring trench. Therefore, the content ratio of the prescribed metallic element in the copper film (the copper wiring) arranged in the wiring trench can be reduced. Consequently, the resistance of the copper film (the copper wiring) arranged in the wiring trench can be reduced.

The deposited metal removing step may be a step of removing the prescribed metallic element on the wiring trench by grinding the insulating film and the copper film embedded in the wiring trench.

The method of manufacturing a semiconductor device may further include a barrier film forming step of forming a barrier film made of a compound of an element constituting the insulating film and the prescribed metallic element on an interface between the insulating film and the alloy film by performing heat treatment after the copper film laminating step and before the unnecessary film portion removing step.

Another aspect of the present invention provides a semiconductor device including: an insulating film having a wiring trench on the surface thereof; a copper wiring embedded in the wiring trench; and a barrier film which is made of a compound of an element constituting the insulating film and a prescribed metallic element and is interposed between the inner surface of the wiring trench and the copper wiring, while the content ratio of the prescribed metallic element in the copper wiring is in the range of 0 to 1 at % on the boundary between the copper wiring and the barrier film (including 0 and 1).

This semiconductor device can be obtained by the aforementioned manufacturing method.

The prescribed metallic element may be manganese. If the material of the insulating film is SiO₂ in this case, a barrier film made of MnₓSi_{y}O_{z} (x, y, z: numbers greater than zero) is formed on the interface between the alloy film and the insulating film.

The foregoing and other objects, features and advantages of the present invention will become apparent from the following description of the embodiments given with reference to the appended drawings.

### BRIEF DESCRIPTION OF THE DRAWINGS

FIG. 1(a) is a schematic sectional view for illustrating a method of manufacturing a semiconductor device according to an embodiment of the present invention.

FIG. 1(b) is a schematic sectional view for illustrating the step subsequent to the step shown in FIG. 1(a).

FIG. 1(c) is a schematic sectional view for illustrating the step subsequent to the step shown in FIG. 1(b).

FIG. 1(d) is a schematic sectional view for illustrating the step subsequent to the step shown in FIG. 1(c).

FIG. 1(e) is a schematic sectional view for illustrating the step subsequent to the step shown in FIG. 1(d).

FIG. 1(f) is a schematic sectional view for illustrating the step subsequent to the step shown in FIG. 1(e).

FIG. 1(g) is a schematic sectional view for illustrating the step subsequent to the step shown in FIG. 1(f).

FIG. 2 is a graph showing the results of a resistance measurement test.

FIG. 3 is a graph showing the relation between the content ratio of Mn in Cu and the specific resistance of Cu.

### DETAILED DESCRIPTION OF PREFERRED EMBODIMENTS

Embodiments of the present invention are now described in detail with reference to the drawings.

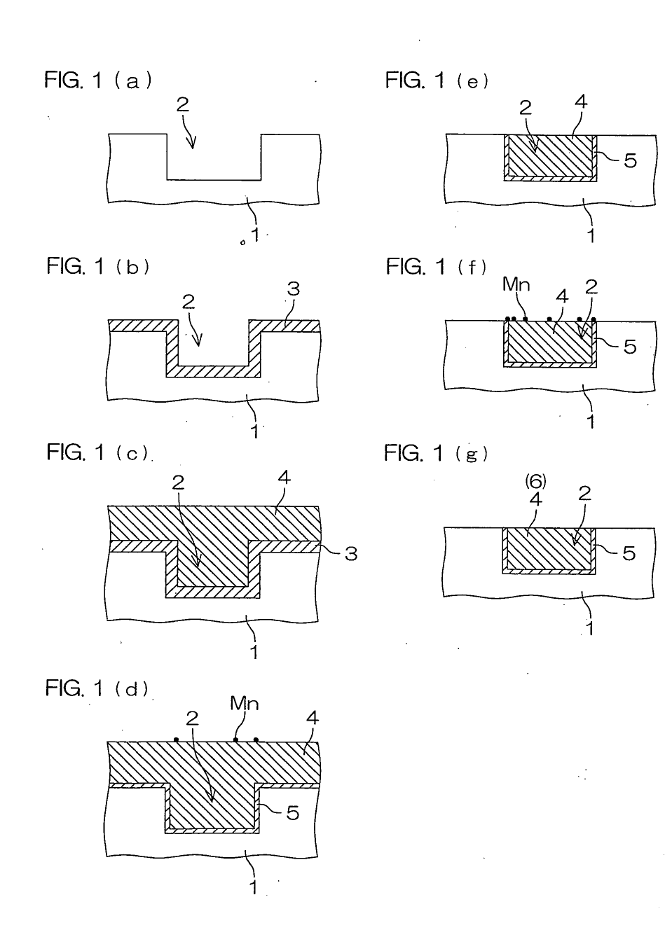

FIGS. 1(a) to 1(g) are sectional views schematically showing the steps in a method of manufacturing a semiconductor device according to the embodiment of the present invention.

First, a concave wiring trench 2 is formed on the surface of an insulating film 1 made of SiO₂, as shown in FIG. 1(a). The insulating film 1 is laminated on a semiconductor substrate (not shown) such as a silicon substrate. Functional elements such as transistors are formed on the semiconductor substrate. The wiring trench 2 can be formed by well-known photolithography and etching.

Then, the entire surface of the insulating film 1 including the inner surface of the wiring trench 2 is coated by sputtering with an alloy film 3 made of an alloy of Cu and Mn, as shown in FIG. 1(b). This alloy film 3 contains 1 to 4% (at %) of Mn in atom number, for example. When the width of the wiring trench 2 (the width in the direction perpendicular to the longitudinal direction in plan view) is 90 to 140 nm, the alloy film 3 is formed in the thickness of 30 to 90 nm, for example.

Then, a Cu film 4 is formed on the alloy film 3 (the insulating film 1) by plating, as shown in FIG. 1(c). This Cu film 4 is formed in a thickness with which it fills up the wiring trench 2 and covers the entire surface of the alloy film 3.

Thereafter the structure including the insulating film 1, the alloy film 3 and the Cu film 4 is introduced into an annealing furnace (not shown) and subjected to heat treatment (annealing) in an N₂ (nitrogen) atmosphere under a temperature condition of 350° C. for 60 minutes, for example. Due to this heat treatment, Mn contained in the alloy film 3 diffuses, so that a barrier film 5 made of MnₓSi_{y}O_{z} (x, y, z: numbers greater than zero) is formed on the interface between the alloy film 3 and the insulating film 1, as shown in FIG. 1(d). At this time, Mn contained in the alloy film 3 partially moves in the Cu film 4, and is deposited on the Cu film 4. With the formation of the barrier film 5, the alloy film 3 is generally integrated with the Cu film 4.

Then, the Cu film 4 and the barrier film 5 are polished by CMP. This polishing is continued until unnecessary portions of the Cu film 4 and the barrier film 5 formed outside the wiring trench 2 are entirely removed, the surface of the insulating film 1 outside the wiring trench 2 is exposed and this surface of the insulating film 1 and the surface of the Cu film 4 in the wiring trench 2 are flush with each other, as shown in FIG. 1(e). Thus, the Cu film 4 and the barrier film 5 remain only in the wiring trench 2.

Thereafter the structure shown in FIG. 1(e) is reintroduced into the annealing furnace and subjected to heat treatment (annealing) in an N₂ atmosphere under a temperature condition of 400° C. for hours, for example. Due to this second heat treatment, unnecessary Mn contained in the Cu film 4 and the barrier film 5 moves in the Cu film 4 and the barrier film 5, and is deposited on the Cu film 4 and the barrier film 5, as shown in FIG. 1(f).

After the second annealing, the insulating film 1, the Cu film 4 and the barrier film 5 are polished by CMP. Due to this polishing, Mn deposited on the Cu film 4 and the barrier film 5 is removed as shown in FIG. 1(g). Thus, a Cu wiring 6 embedded in the wiring trench 2 is obtained. The Mn content ratio in this Cu wiring 6 is in the range of 0 to 1 at % (including 0 and 1) on the boundary between the Cu wiring 6 and the barrier film 5.

As hereinabove described, the wiring trench is formed on the surface of the insulating film 1, and the surface of the insulating film 1 including the inner surface of the wiring trench 2 is thereafter coated with the alloy film 3 made of the alloy of Cu and Mn. After this coating with the alloy film 3, the Cu film 4 is laminated on the insulating film 1 to fill up the wiring trench 2. Thereafter the first heat treatment is performed to form the barrier film 5 made of MnₓSi_{y}O_{z} on the interface between the alloy film 3 and the insulating film 1. Then, the unnecessary portions of the Cu film 4 and the barrier film 5 outside the wiring trench 2 are removed. Thereafter the second heat treatment is performed. Due to this heat treatment, Mn is deposited on the wiring trench 2. Then, Mn deposited on the wiring trench 2 is removed.

When the unnecessary portions of the Cu film 4 outside the wiring trench 2 are removed, the Cu film 4 is reduced in thickness and the grain boundaries of Cu atoms not clogged with impurities are exposed on the surface of the Cu film 4 in the wiring trench 2. In the heat treatment after this removal of the unnecessary portions, therefore, Mn easily moves along the grain boundaries in the Cu film 4. Further, the unnecessary portions of the barrier film 5 are also removed along with those of the Cu film 4, so that the surface of the barrier film 5 covering the inner side surface of the wiring trench 2 is exposed. Thus, Mn moves in the Cu film 4 and the barrier film 5, to be excellently deposited on the wiring trench 2 (on the Cu film 4 and the barrier film 5). Therefore, the Mn content ratio in the Cu film 4 (the Cu wiring 6) embedded in the wiring trench 2 can be reduced. Consequently, the resistance of the Cu film 4 (the Cu wiring 6) arranged in the wiring trench 2 can be reduced.

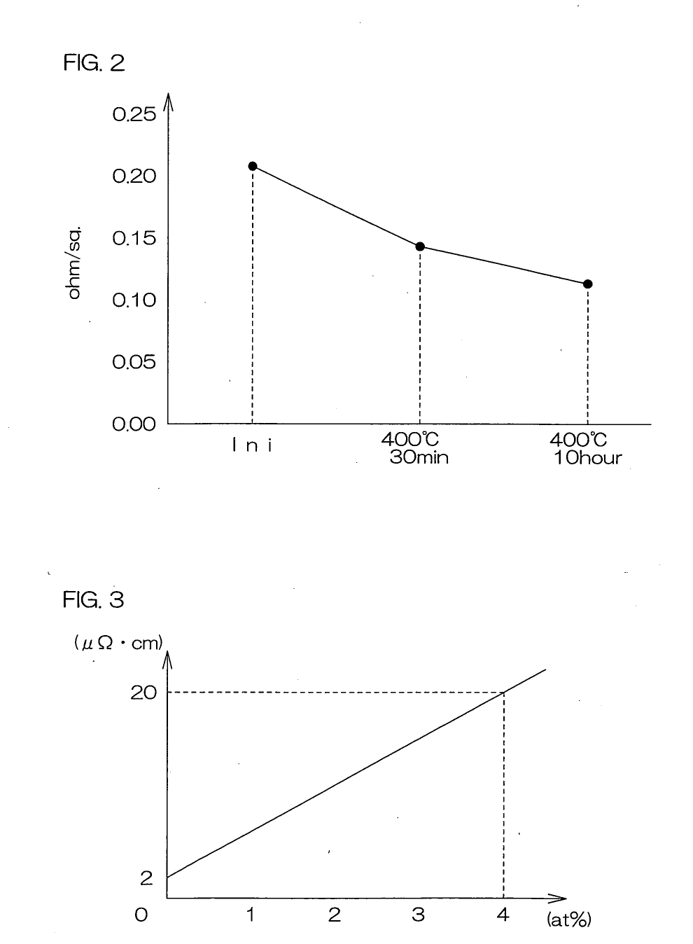

FIG. 2 is a graph showing the results of a resistance measurement test.

In order to confirm the effect of the heat treatment performed after the removal of the unnecessary portions of the Cu film 4 and the barrier film 5 outside the wiring trench 2, the resistance values of the Cu film 4 in the wiring trench 2 were measured as to a case of performing no heat treatment (the heat treatment time was 0 (zero)), a case of performing heat treatment for 30 minutes and a case of performing heat treatment for 10 hours respectively. The width of the wiring trench 2 was set to 120 nm in the direction perpendicular to the longitudinal direction in plan view.

As shown in FIG. 2, the resistance value of the Cu film 4 was about 0.20 ohm/sq. in the case of performing no heat treatment (Ini). In the case of performing the heat treatment for 30 minutes, the resistance value of the Cu film 4 was about 0.15 ohm/sq. In the case of performing the heat treatment for 10 hours, the resistance value of the Cu film 4 was about 0.11 ohm/sq.

It is understood from the results of this resistance measurement test that the resistance of the Cu film 4 (the Cu wiring 6) embedded in the wiring trench 2 can be reduced by performing the heat treatment after the removal of the unnecessary portions of the Cu film 4 and the barrier film 5 outside the wiring trench 2.

While Mn deposited on the barrier film 5 and the Cu wiring 6 is removed through polishing by CMP in the aforementioned embodiment, this Mn deposited on the barrier film 5 and the Cu wiring 6 may alternatively be removed by etching with acid such as HCl (hydrochloric acid).

Further, while the material of the insulating film 1 is SiO₂ in the aforementioned embodiment, the insulating film 1 may alternatively be made of a Low-k film material such as SiOC or SiOF, in place of SiO₂.

Although the present invention has been described and illustrated in detail, it is clearly understood that the same is by way of illustration and example only and is not to be taken by way of limitation. The spirit and scope of the present invention is limited only by the terms of the appended claims.

This application corresponds to the Japanese Patent Application No. 2006-320649 filed with the Japan Patent Office on Nov. 28, 2006, the disclosure of which is incorporated herein by reference in entirety.

What is claimed is:

1. A method of manufacturing a semiconductor device, comprising:
a wiring trench forming step of forming a wiring trench on a surface of an insulating film;
an alloy film coating step of coating an inner surface of the wiring trench with an alloy film made of an alloy material containing copper and a prescribed metallic element;
a copper film stacking step of stacking a copper film on the insulating film to fill up the wiring trench after the alloy film coating step;
an unnecessary film portion removing step of removing an unnecessary portion of the copper film outside the wiring trench;
a metallic element depositing step of depositing the prescribed metallic element on the wiring trench by performing heat treatment after the unnecessary film portion removing step; and
a deposited metal removing step of removing the prescribed metallic element deposited on the wiring trench after the metallic element depositing step.

2. The method of manufacturing a semiconductor device according to claim 1, wherein the deposited metal removing step is a step of removing the prescribed metallic element on the wiring trench by grinding the insulating film and the copper film embedded in the wiring trench.

3. The method of manufacturing a semiconductor device according to claim 1, further comprising a barrier film forming step of forming a barrier film Made of a compound of an element constituting the insulating film and the prescribed metallic element on an interface between the insulating film and the alloy film by performing heat treatment after the copper film stacking step and before the unnecessary film portion removing step.

4. The method according to claim 3, wherein the unnecessary film portion removing step includes a step of removing the unnecessary portion of the copper film outside the wiring trench such that the barrier film is exposed from a surface of the insulating film.

5. The method according to claim 3, wherein the barrier film is made of MnₓSi_{y}O_{z}, where x, y and z are numbers greater than zero.

6. The method of manufacturing a semiconductor device according to claim 1, wherein the prescribed metallic element is manganese.

7. The method according to claim 6, wherein a content ratio of manganese in the alloy film is in a range of 1 to 4 wt %.

8. The method according to claim 1, wherein the insulating film is made of a low-k film material.

9. The method according to claim 1, wherein the deposited metal removing step includes etching with acid.
